(19) United States
(12) Patent Application Publication
(10) Pub. No.: US 2010/0194465 A1
(43) Pub. Date: Aug. 5, 2010

(54) TEMPERATURE COMPENSATED CURRENT SOURCE AND METHOD THEREFOR

(76) Inventors: Ali Salih, Mesa, AZ (US); Thomas Keena, Chandler, AZ (US); Jefferson W. Hall, Chandler, AZ (US)

Correspondence Address: SEMICONDUCTOR COMPONENTS INDUSTRIES, LLC;INTELLECTUAL PROPERTY DEPT. - A700, 5005 E. MCDOWELL ROAD, P.O.BOX 62890, PHOENIX, AZ, 85082, US

(21) Appl. No.: 12/364,242

(22) Filed: Feb. 2, 2009

(51) Int. Cl. H01L 37/00; H01L 21/00

(52) U.S. Cl. 327/513; 29/25.01

(57) ABSTRACT

In one embodiment, a temperature compensated current source includes a depletion mode transistor coupled in series with an active semiconductor device that adjust the depletion mode transistor to minimize variations in the current due to temperature changes.

### BACKGROUND OF THE INVENTION

The present invention relates, in general, to electronics, and more particularly, to semiconductors, structures thereof, and methods of forming semiconductor devices.

Light emitting diodes (LEDs) are gaining acceptance as a light source in a variety of applications that previously used incandescent light sources. In the past, complex circuits such as series-pass voltage regulators or switching voltage regulators or switching current regulators were used to provide a power source for operating the LEDs. Some examples of such power sources are disclosed in U.S. Pat. No. 6,285,139 and United States patent publication number 2007/0024259. These previous power sources contained many elements which resulted in a high cost for using an LED as a light source. In addition, many of these power sources did not provide a stable current to the LEDs as the value of the ambient temperature changed thereby causing undesirable variation in the intensity of the emitted light.

Accordingly, it is desirable to have a lower cost circuit and method that controls a current, and a circuit and method that provides a more stable current due to temperature changes.

### BRIEF DESCRIPTION OF THE DRAWINGS

FIG. 1 schematically illustrates an embodiment of a portion of an LED lighting system that includes a temperature compensated current source in accordance with the present invention;

FIG. 2 schematically illustrates an embodiment of an LED lighting system;

FIG. 3 schematically illustrates an embodiment of a portion of another light emitting system that includes an alternate embodiment of the temperature compensated current source of FIG. 1 in accordance with the present invention;

FIG. 4 schematically illustrates an embodiment of a portion of another temperature compensated current source that is an alternate embodiment of the temperature compensated current source of FIG. 1 in accordance with the present invention;

FIG. 5 schematically illustrates an embodiment of a portion of another temperature compensated current source that is an alternate embodiment of the temperature compensated current source of FIG. 1 in accordance with the present invention;

FIG. 6 schematically illustrates an embodiment of a portion of another temperature compensated current source that is yet another alternate embodiment of the temperature compensated current source of FIG. 1 in accordance with the present invention; and

FIG. 7 illustrates an enlarged cross-sectional view of a portion of a semiconductor device that includes the temperature compensated current source of FIG. 1 in accordance with the present invention.

For simplicity and clarity of the illustration, elements in the figures are not necessarily to scale, and the same reference numbers in different figures denote the same elements. Additionally, descriptions and details of well-known steps and elements are omitted for simplicity of the description. As used herein current carrying electrode means an element of a device that carries current through the device such as a source or a drain of an MOS transistor or an emitter or a collector of a bipolar transistor or a cathode or anode of a diode, and a control electrode means an element of the device that controls current through the device such as a gate of an MOS transistor or a base of a bipolar transistor. Although the devices are explained herein as certain N-channel or P-Channel devices, or certain N-type or P-type doped regions, a person of ordinary skill in the art will appreciate that complementary devices are also possible in accordance with the present invention. It will be appreciated by those skilled in the art that the words during, while, and when as used herein relating to circuit operation are not exact terms that mean an action takes place instantly upon an initiating action but that there may be some small but reasonable delay, such as a propagation delay, between the reaction that is initiated by the initial action. The use of the word approximately or substantially means that a value of an element has a parameter that is expected to be very close to a stated value or position. However, as is well known in the art there are always minor variances that prevent the values or positions from being exactly as stated. It is well established in the art that variances of up to at least ten per cent (10%) (and up to twenty per cent (20%) for semiconductor doping concentrations) are reasonable variances from the ideal goal of exactly as described. For clarity of the drawings, doped regions of device structures are illustrated as having generally straight line edges and precise angular corners.

### DETAILED DESCRIPTION OF THE DRAWINGS

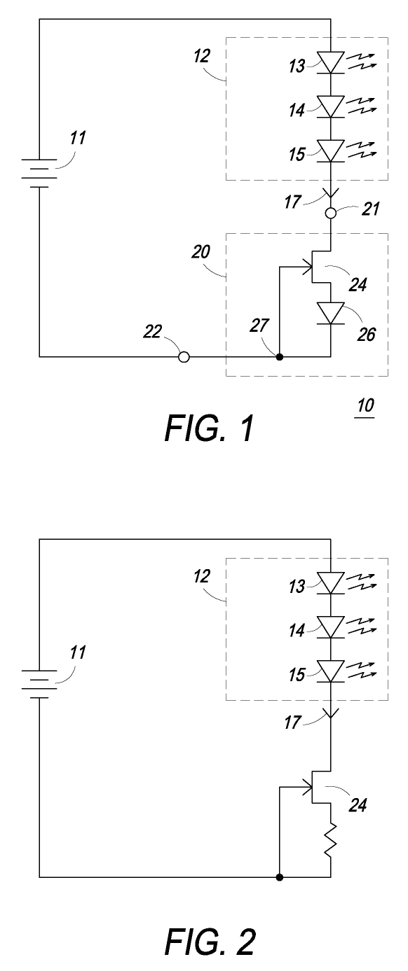

FIG. 1 schematically illustrates an embodiment of a portion of an LED lighting system 10 that includes a temperature compensated current source 20. System 10 includes a voltage source that provides a dc voltage for operating system 10. The voltage source may be a variety of dc voltage sources including a battery, a switching voltage regulator, a series-pass voltage regulator, or other well-known type of dc voltage source. In some embodiments, the DC voltage source may be the voltage resulting from a full-wave or half-wave rectified ac voltage. For purposes of explaining system 10 and source 20, the dc voltage source is illustrated as a battery 11. The exemplary embodiment of system 10 also includes a load that is configured as an LED light source 12 that is utilized for emitting light. Generally, source 12 includes a plurality of LEDs illustrated as LEDs 13-15. However, light source 12 could include a single LED or more than the three (3) LEDs illustrated in FIG. 1. Those skilled in the art will realize that the load could be another type of load that needs to operate with a current source such as source 20. For the illustrated embodiment, temperature compensated current source 20 is a two (2) terminal semiconductor device that includes a first terminal 21 and a second terminal 22. As illustrated in FIG. 1, terminal 21 is an input terminal and terminal 22 is an output terminal. Source 20 also includes a depletion mode transistor 24 and an active semiconductor device that is in series with transistor 24. Transistor 24 preferably is an N-channel depletion mode device that is normally on at a gate-to-source voltage (Vgs) of approximately zero volts, such as an N-channel depletion mode metal oxide semiconductor field effect transistor (N-channel depletion mode MOSFET) or an N-channel junction field effect transistor (N-channel JFET). In the preferred embodiment, transistor 24 is an N-channel JFET. The current through transistor 24 increases with increasing drain-to-source voltage until the current reaches saturation. The saturation current level is also controlled by Vgs. The usual transistor family of characteristic voltage-current (V-I) curves is generated by deceasing Vgs from zero to negative values. For example, the threshold voltage of an N-channel JFET usually is somewhere in the range of minus two to minus six volts (−2V to −6V). When Vgs is less negative than the threshold voltage, the JFET operates in the saturation region, when Vgs reaches the threshold voltage the channel of the JFET becomes pinched off and the JFET reverts from the saturation region to the pinched-off or off-state.

As will be seen further hereinafter, transistor 24 and the active semiconductor device are configured so that transistor 24 can receive and conduct a current that also flows through the active semiconductor device to a common node 27 of source 20. Additionally, source 20 is configured to use temperature induced changes in the value of a voltage across the active semiconductor device to adjust the Vgs of transistor 24. For the embodiment illustrated in FIG. 1, the active semiconductor device is a P-N junction diode 26. Those skilled in the art will understand that diode 26 may also be a Schottky (metal-semiconductor junction) diode or a zener diode. The gate of transistor 24 is connected to common node 27 which is also connected to terminal 22. An anode of diode 26 is connected to a source of transistor 24 and a cathode of diode 26 is connected to common node 27. A drain of transistor 24 is connected to terminal 21 and a gate is connected to node 27. In one embodiment, source 20 is formed on a semiconductor substrate as an integrated circuit having two external leads or terminals 21 and 22.

Battery 11 provides power for operating LEDs 13-15 and source 20. The voltage from battery 11 forms current 17 which flows through LEDs 13-15 to source 20. Current 17 flows through transistor 24 and diode 26 to common node 27, then through terminal 22 back to battery 11. Current 17 flowing through diode 26 causes a voltage drop across diode 26 that is equal to the forward voltage of diode 26. In the preferred embodiment, the value of current 17 are selected to operate diode 26 at a point in the voltage-current (V-I) characteristic curve of diode 26 that is no less than the knee of the V-I characteristics. Additionally, the value of current 17 are selected so that transistor 24 is operating in the saturation region of the V-I characteristic curve for transistor 24.

For a given constant voltage from battery 11 and a given value of current 17, it is important to keep the value of current 17 substantially constant as temperature changes in order to keep the intensity of the light emitted by LEDs 13-15 substantially constant. The temperature increase may result from a change in the ambient environment, such as an automobile taillight that is exposed to direct sunlight that heats system 10, or it may result from heat from the operation of the LEDs or of source 20. The increased temperature of source 20 increases the internal resistance of transistor 24 thereby causing a reduction of the current that is conducted by transistor 24. The increase in temperature of diode 26 decreases the value of the voltage drop across diode 26 thereby lowering the value of the voltage applied to the source of transistor 24 (making the source closer to the voltage of node 27). Lowering the voltage applied to the source increases the Vgs (makes Vgs less negative and closer to zero) by the same absolute value as the absolute value of the change in the forward voltage drop across diode 26. The increased Vgs causes transistor 24 to conduct more current thereby minimizing the variation in the value of current 17 due to the increased temperature change. Those skilled in the art will understand that the threshold voltage of transistor 24 may vary some in response to the temperature change, but the threshold variation is much smaller than the change n the voltage across diode 26, therefore, the threshold voltage can be considered to be substantially constant. For the preferred embodiment of transistor 24 as a JFET, the less negative Vgs or increased Vgs also decreases the pinch-off, thereby reducing the resistance of the JFET, and allowing more current to flow through the channel of the JFET. As a result, the current flow through transistor 24 and source 20 remains substantially constant as the temperature increases. For the embodiment of transistor 24 as an N-channel depletion mode MOSFET, the increased Vgs causes the channel of transistor 24 to conduct more current. For example, in one embodiment diode 26 had a fifty volt (50V) reverse breakdown and transistor 24 was a JFET with the value of current 17 set to approximately thirty milli-amperes (30 mA) at twenty five (25) degrees Celsius. As the temperature increased from twenty five to one hundred twenty five (25-125) degrees Celsius, the forward voltage decreased about 0.1 to 0.2 volts which caused a corresponding 0.1 to 0.2 volt increase in the Vgs of a JFET transistor. The Vgs increase also increased the value of current 17 approximately one to three milli-amperes which represents an approximately three to ten percent 3%-10%) current compensation.

Those skilled in the art will appreciate that a decrease in temperature would decrease the internal resistance of transistor 24 thereby causing an increase in the amount of current that could be conducted by transistor 24 (for a constant Vgs). The decreased temperature of diode 26 increases the voltage drop across diode 26 thereby increasing the voltage on the source of transistor 24. Increasing the value of the voltage on the source of transistor 24 decreases the Vgs (makes Vgs more negative) which causes transistor 24 to conduct less current. As a result, the current flow through transistor 24 and source 20 remains substantially constant as the temperature decreases. As a result, the current flow through transistor 24 and source 20 remains substantially constant as the temperature decreases.

Consequently, it can be seen that the current flow through transistor 24 and source 20 remains substantially constant as the temperature increases and decreases. Typically, the value of current 17 varies at a rate of only about 0.03 to 0.08 mA/degree Centigrade depending on the size and design of the diode 26 for a temperature of about minus forty to plus one hundred twenty five (−40 to 125) degrees Centigrade for current 17 at about thirty milli-Amperes (30 mA.). For comparison, typical prior art devices have a rate of change of over 0.17 mA/degree Centigrade which usually is several times larger than the change of source 20.

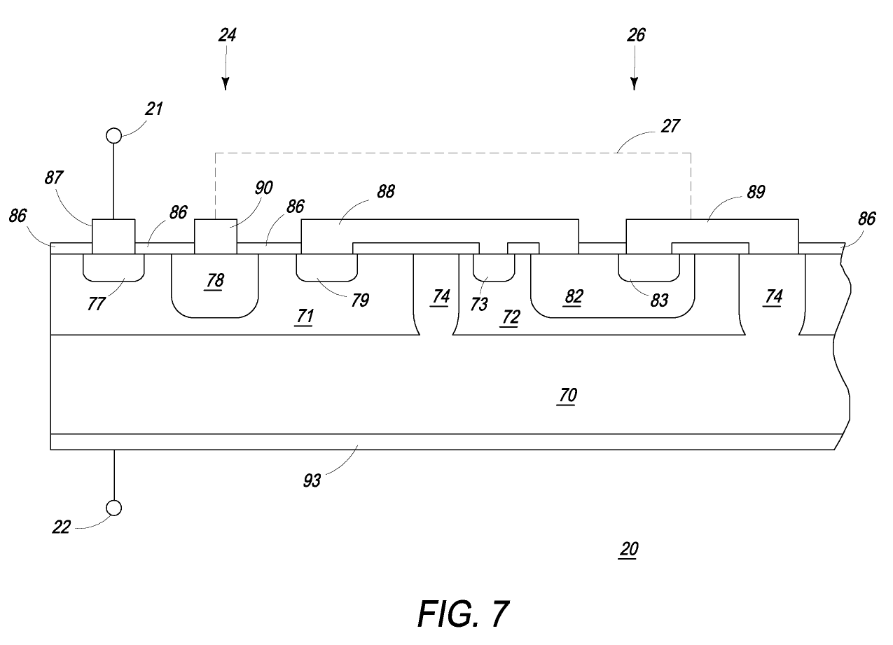

An alternate embodiment of forming source 20 forms transistor 23 and diode 26 to block current flow from terminal 22 to terminal 21 thereby limiting current 17 to flow in only one direction through source 20 and light source 12. This could provide an additional advantage of preventing reverse current flow through system 10. The alternate embodiment is similar to the embodiment of FIG. 7 except that substrate 70 is changed to an N-type conductivity. Then a P-type doped region (often referred to as a tub or well) is formed to enclose region 71. Thereafter, region 71 and regions 77, 78, and 79 are formed the same as explained n the description of FIG. 7. In this alternate embodiment, region 72 may be omitted or may be used to provide the same conductivity type but a different doping concentration than substrate 70.

If the value of the voltage from battery 11 increases (at a given temperature), such as if battery 11 is charged, the value of current 17 would begin to increase. Because of the sharp knee of diode 26, one skilled in the art normally would expect that the change in voltage would cause the value of current 17 to increase. However, it has been found that source 20 also minimizes variations in the value of current 17 as the voltage from battery 11 increases and decreases. Because diode 26 has a sharp knee, the change of the input voltage has substantially no effect on the voltage drop across diode 26, thus, the Vgs of transistor 24 remains substantially constant. Therefore, for a set temperature value, source 20 provides the unexpected result of controlling the current through source 20 to remain substantially constant as the input voltage changes.

In one example embodiment, system 10 included three (3) serial LEDs 13-15 with each having a nominal forward voltage of about one and one-half volts to four volts (1.5V to 4.0V). Also, transistor 24 had a pinch-off voltage of approximately minus three volts (−3V), source 20 conducted a current of approximately five hundred milli-amperes (500 mA.) at room temperature and the knee of diode 26 occurred at a forward voltage of approximately 0.75 volts. The operation of system 10 was compared to a system using transistor 24 connected to a resistor instead of diode 26 such as illustrated in FIG. 2. The selected value of the resistor was twenty-four ohms, however, other resistor values could be used. Table 1 below shows the variation in current 17 at a substantially constant temperature for two voltages of battery 11, about eight volts (8V) and about eighteen volts (18V):

TABLE 1
Comparison Table

| | Current value for | Current value for |
|---|---|---|
| Battery Voltage | Source 20 | FIG. 2 System |
| 8 volts | 17.9 mA | 29.2 mA |
| 18 volts | 17.0 mA | 26.0 mA |
| Current variation | 4.52% | 10.96% |

As can be seen from Table 1, source 20 has the unexpected result of also minimizing the variations of current 17 due to changes in the value of the voltage used for operating source 20 and system 10 (at a given value of temperature). Furthermore, source 20 also has a lower total current consumption resulting in lower power dissipation. Table 1 indicates that, at a given temperature, source 20 controls the variation of current 17 to be no greater than about five per cent (5%) as the voltage doubles. Those skilled in the art will understand that if the value of the voltage from battery 11 decreases, then the value of current 17 would also decrease in a manner similar to that described for the increase of current 17.

It is believed that the variation in light intensity emitted by LEDs 13-15 due to temperature variations is greater than the light intensity variation due to variations of the operating voltage, thus, it is believed that minimizing the variation of current 17 over a range of temperatures, for a given value of voltage from battery 11, is important.

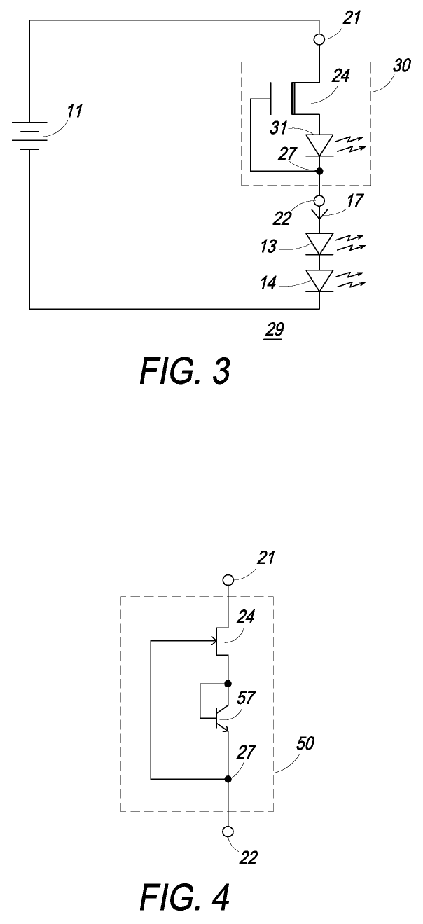

FIG. 3 schematically illustrates an embodiment of a portion of another light emitting system 29 that is an alternate embodiment of light emitting system 10 that was explained in the description of FIG. 1. System 10 includes a temperature compensated current source 30 that is similar to source 20 except that diode 26 of source 20 is replaced by an LED 31. In some embodiments, LED 31 may also be one of the plurality of LEDs that are used for emitting light either by LED 31 alone or in conjunction with other LEDs such as LEDs 13 and 14. In FIG. 3, transistor 24 is illustrated as an N-channel depletion mode MOSFET. In the preferred embodiment, the voltage from battery 11 and the value of current 17 are selected to operate LED 31 in a manner similar to diode 26. Since an LED operating in the visible spectrum has a higher forward voltage drop than a silicon P-N junction diode or a metal-semiconductor junction diode, the voltage variation across the LED is greater for temperature changes. Therefore, source 30 has less current variations due to temperature changes than source 20. It has been found that source 30 limits variations of current 17 to less than about 0.03 ma/degree Centigrade over a temperature range of about minus forty to plus one hundred twenty five (−40 to 125) degrees Centigrade (at a constant value of battery 11) and to less than about five percent (5%) of current 17 for the voltage variations explained in the description of Table 1.

FIG. 4 schematically illustrates an embodiment of a portion of a temperature compensated current source 50 that is an alternate embodiment of source 20. Source 50 is similar to source 20 except that source 50 includes a diode connected bipolar transistor 51 instead of diode 26. Source 50 operates similarly to source 20.

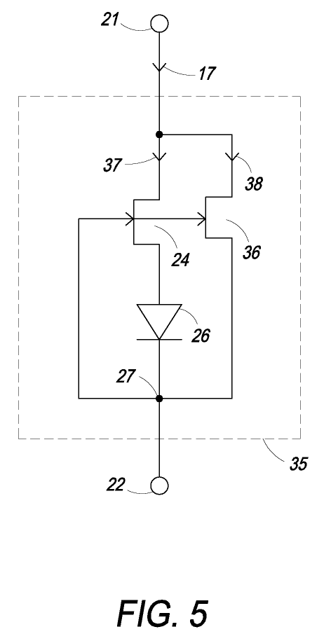

FIG. 5 schematically illustrates an embodiment of a portion of a temperature compensated current source 35 that is another alternate embodiment of source 20. Source 35 includes a depletion mode transistor 36 that is connected in a current mirror configuration with transistor 24. Transistor 36 is similar to transistor 24. Because of the current mirror configuration, a portion of current 17 flows through transistor 24 as a current 37 and another portion of current 17 flows through transistor 36 as a current 38. The percentage of current 17 that flows through transistors 24 and 36 is determined by the ratio of the sizes of transistors 24 and 36, assuming that transistor 36 is a current mirror of 24 having the same or similar threshold voltage and preferably monolithically formed on the same semiconductor substrate. As the temperature varies, the voltage drop across diode 26 adjusts the Vgs of transistor 24 to minimize the variations of current 37 similar to the operation described for source 20 relative to current 17. The gates of transistors 24 and 36 are at the same potential due to the common connection. Transistor 36 and diode 26 form a temperature-compensated current source similar to the operation explain for source 20 in the description of FIG. 1. As temperature increases the gate-to-source voltage (Vgs) for both transistors 24 and 36 increases which increases the value of current 17. This configuration provides a constant current source while placing the compensating diode feedback away from the path of the main current flow. As will be see by those skilled in the art, the size ratio of transistors 24 and 36 may be changed so that the value of current 37 is less than current 38. Such a configuration can decrease the power dissipation of source 35. In the preferred embodiment, a drain of transistor 36 is connected to the drain of transistor 24, and a source of transistor 36 is connected to node 27. Because, current 37 typically is less than current 37, the power dissipation and associated heat generated in transistor 24 and diode 28 is reduced. Those skilled in the art will appreciate that the configuration of transistor 36 may be used for any of sources 20, 30, or 50.

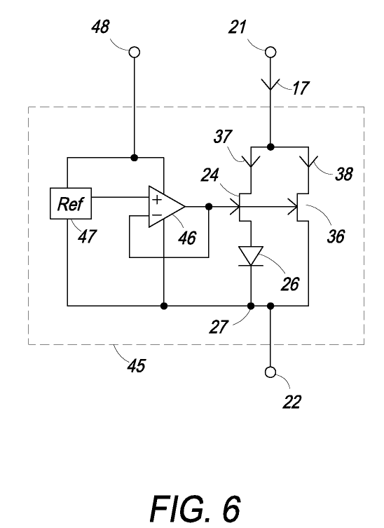

FIG. 6 schematically illustrates an embodiment of a portion of a temperature compensated current source 45 that is another alternate embodiment of source 35 that was explained in the description of FIG. 5. However, source 45 includes a feedback control loop that assists in controlling current 17. The gate of transistors 24 and 36 are configured to be controlled by the feedback control loop. The feedback control loop includes a reference generator or ref 47 that generates a reference voltage, and an amplifier 46 that is configured to monitor the Vgs of transistor 24 and to control the Vgs. In the illustrated embodiment, the control loop controls the Vgs of transistor 24 to be approximately equal to the value of the reference voltage from ref 47 minus the voltage drop across diode 26. As the value of the voltage across diode 26 varies with temperature variations, the output of amplifier 46 adjusts the Vgs of transistor 24 such that the voltage from the gate of transistor 24 to the cathode of diode 26 is substantially equal to the voltage from ref 47 in order to maintain the value of currents 37 and 38 to be substantially constant. The output of source 45 is terminal 22 since current 17 flows out of source 20 through terminal 22. Source 45 generally includes another terminal 48 that is used to provide power for operating amplifier 46 and ref 47. In some embodiments, terminal 48 may be omitted and terminal 21 may also be connected to supply operating power for amplifier 46. Those skilled in the art will appreciate that the control loop of source 45 may also be used for the configuration of any of sources 20, 30, or 50.

FIG. 7 illustrates an enlarged cross-sectional view of a portion of source 20. Source 20 is formed on a semiconductor substrate 70 having a first surface and a second surface. A region 71 that has a conductivity type that is opposite to substrate 70 is formed on the first surface of substrate 70. A region 72 that has a conductivity type that is opposite to substrate 70 is also formed on the first surface of substrate 70 and spaced apart from region 71. A region 74 that has the conductivity type of substrate 70 is positioned to isolate region 72 from region 71 thereby isolating transistor 24 from diode 26. In the preferred embodiment, region 74 surrounds region 72 with a topology of a multiply-connected domain. The term “multiply-connected” means a connected domain that has one or more holes in it (such as a doughnut). Transistor 24 is formed in region 71 and diode 26 is formed in region 72. Region 74 may be a portion of substrate 70 that remains after the surface of substrate 70 is doped to form regions 71 and 72, such as by implanting regions 71 and 72. Alternately, an epitaxial layer may be formed on substrate 70 and a portion of the epitaxial layer may be doped to form region 74. In the preferred embodiment of transistor 24 as an N-channel depletion mode transistor, substrate 70 and region 74 have a P-type conductivity and regions 71 and 72 have an N-type conductivity. Regions 71 and 72 may be formed at the same time during the same processing step or steps. Drain and source regions of transistor 24 are formed as respective doped regions 77 and 79 on the surface of substrate 70 within region 71. Regions 77 and 79 may be formed at the same time during the same processing step or steps. A doped region 78 that has the same conductivity as substrate 70 is formed on the surface of substrate 70 within region 71 and positioned between regions 77 and 79. A doped region 82 that has the same conductivity as substrate 70 is formed on the surface of substrate 70 within region 72. A doped region 83 that has a conductivity type that is opposite to region 82 is formed within region 82. Regions 78 and 82 may be formed at the same time during the same processing step or steps. Region 83 may be formed simultaneously with regions 77 and 79. Regions 82 and 83 form the respective anode and cathode of diode 26. A conductor 87 makes electrical contact to region 77 to form a drain conductor for transistor 24. Conductor 87 typically is connected to terminal 21. One end of a conductor 88 makes electrical contact to region 79 to form a source conductor for transistor 24. The other end of conductor 88 makes electrical contact to regions 72 and 82 to form an anode conductor for diode 26. Depending on the doping concentration of region 72, another doped region 73 that is the same doping type as region 72 and a heavier doping concentration may be needed to form a good ohmic contact to region 72. Depending on the doping concentration of region 82, another doped region (not shown) that is the same doping type as region 82 and a heavier doping concentration may be needed to form a good ohmic contact to region 82. Conductor 88 electrically connects the source of transistor 24 to the anode of diode 26. One end of a conductor 89 makes electrical contact to region 83 to form a cathode conductor for diode 26. The other end of conductor 89 makes electrical contact to a portion of region 74 to form an electrical connection between the cathode of diode 26 and terminal 22 through region 74 and substrate 70. The portion of region 74 that electrically connects to conductor 89 generally is not the portion that is between regions 71 and 72. A dielectric 86 isolates portions of conductors 88 and 89 from other portions of substrate 70. A conductor 90 makes electrical contact to region 78 to form a gate conductor for transistor 24. Conductor 90 typically is routed around the surface of substrate 70 to electrically contact conductor 89. This electrical connection forms node 27 as illustrated by a dashed line in FIG. 8. A conductor 93 is usually applied to the second surface of substrate 70 and is subsequently connected to terminal 22.

Substrate 70 may also include other circuits that are not shown in FIG. 8 for simplicity of the drawing. Source 20 is formed on substrate 70 by semiconductor manufacturing techniques that are well known to those skilled in the art. Any of sources 30, 35, or 50, and combinations thereof, may be formed on substrate 70 along with or instead of source 20. Source 40 or 45 may also be formed on substrate 70 as a device having three leads or terminals.

Those skilled in the art will appreciate that source 20, or any of sources 30, 35, 45, 50, may be formed on an integrated circuit that includes a variety of other semiconductor elements. In such an embodiment, terminal 22 may be formed on the first surface of substrate 70. For example, terminal 22 may be formed by a connection to conductor 89 to form the electrical connection to the cathode of diode 26 wherein conductor 89 is not necessarily connected to region 74.

In view of all of the above, it is evident that a novel device and method is disclosed. Included, among other features, is forming a depletion mode FET and an active semiconductor device to control a current as the temperature increases. The configuration more accurately controls the value of the current for temperature variations than prior devices. The configuration also does not require extra circuits to apply a positive gate bias in order to form the current thereby eliminating the cost of the extra gate biasing circuitry. The positive gate bias of prior devices also requires a higher operating voltage in order to generate the positive gate bias, therefore, the instant novel device can operate from a lower voltage thereby providing a power saving advantage. In addition, the extra gate bias circuitry also consumes power, thus, the instant novel device provides another power saving advantage. It has also been found that the configuration has the unexpected result of more accurately controlling the current as the applied voltage varies than prior devices.

From the above descriptions, hose skilled in the art will understand that the previously described advantage are obtained from an embodiment of sources 20, 30, 35, and 50 that includes: first and second terminals; a first depletion mode transistor having a control electrode connected to the second terminal, a first current carrying electrode connected to the first terminal, and a second current carrying electrode; and a diode having an anode connected to the second current carrying electrode of the first depletion mode transistor, and a cathode connected to the second terminal.

Those skilled in the art will understand from the previous explanations that the previously described advantages are obtained from a method of forming sources 20, 30, 35, and 50 that includes: coupling a first FET to conduct a current from a first current carrying electrode of the first FET through the first FET; and coupling a semiconductor device that is one of a diode or a depletion mode MOSFET in series with a second current carrying electrode of the first FET wherein the current flows through a common node that is connected to a gate of the first FET and coupled to the active semiconductor device and wherein the gate is not connected to any other node.

Those skilled in the art will understand that the previously described advantages are obtained from a method of forming sources 20, 30, 35, 45, and 50 that includes: coupling a first current carrying electrode of a first FET to receive a current to conduct through the first FET; coupling an active semiconductor device that is one of a diode or a depletion mode MOSFET between a second current carrying electrode of the first FET and a common node of the current source wherein a voltage across the active semiconductor device varies from changes in temperature; and configuring the current source to use changes in a voltage across the active semiconductor device to adjust a gate-to-source voltage of the first FET.

Those skilled in the art will appreciate that a method of forming sources 20, 30, 35, 45, and 50 includes: providing a substrate of a first conductivity type and having first and second surfaces; forming a first doped region having a second conductivity type on the first surface of the substrate; forming a second doped region having the second conductivity type on the first surface of the substrate and spaced apart from the first doped region; forming a region of the first conductivity type between the first and second doped regions; forming third and fourth doped regions of the second conductivity type on the first surface and within the first doped region as respective source and drain regions of a depletion mode transistor; forming a fifth doped region having the first conductivity type on the first surface and within the first doped region wherein the fifth doped region is spaced apart from and between the third and fourth doped regions; forming a sixth doped region having the first conductivity type on the first surface and within the second doped region; forming a seventh doped region having the second conductivity type on the first surface and within the sixth doped region; and forming a first conductor to electrically couple the third doped region to the sixth doped region.

While the subject matter of the invention is described with specific preferred embodiments, it is evident that many alternatives and variations will be apparent to those skilled in the semiconductor arts. More specifically the subject matter of the invention has been described for an N-channel JFET but those skilled in the art realize that other field effect transistors (FETs) including a P-channel JFET, an N-channel depletion mode MOSFET, or a P-channel depletion mode MOSFET may also be used instead of the N-channel JFET. Additionally, a resistor may be inserted in series with the active semiconductor device to provide additional control of the current for variations of the applied voltage. Although the temperature compensated current sources are described as controlling a current through an LED, those skilled in the art will appreciate that the temperature compensated current sources can also be used for applications that require a temperature compensated current. Additionally, the word “connected” is used throughout for clarity of the description, however, it is intended to have the same meaning as the word “coupled”. Accordingly, “connected” should be interpreted as including either a direct connection or an indirect connection.

1. A temperature compensated current source comprising:
first and second terminals;
a first depletion mode transistor having a control electrode connected to the second terminal, a first current carrying electrode connected to the first terminal, and a second current carrying electrode; and
a diode having an anode connected to the second current carrying electrode of the first depletion mode transistor, and a cathode connected to the second terminal.

2. The temperature compensated current source of claim 1 wherein the diode is a P-N junction diode.

3. The temperature compensated current source of claim 1 wherein the diode is a diode connected bipolar junction transistor.

4. The temperature compensated current source of claim 1 wherein the diode is an LED.

5. The temperature compensated current source of claim 1 further including a second depletion mode transistor having a control electrode connected to the control electrode of the first depletion mode transistor, a first current carrying electrode connected to the first terminal, and having a second current carrying electrode.

6. The temperature compensated current source of claim 5 wherein the second current carrying electrode of the second depletion mode transistor is connected to the second terminal.

7. The temperature compensated current source of claim 5 wherein a control electrode of the second depletion mode transistor is connected to the control electrode of the first depletion mode transistor.

8. The temperature compensated current source of claim 1 wherein the temperature compensated current source is formed in a semiconductor package having no more than two terminals.

9. A method of forming a current source comprising:
coupling a first FET to conduct a current from a first current carrying electrode of the first FET through the first FET; and
coupling a semiconductor device that is one of a diode or a depletion mode MOSFET in series with a second current carrying electrode of the first FET wherein the current flows through a common node that is connected to a gate of the first FET and coupled to the active semiconductor device and wherein the gate is not connected to any other node.

10. The method of claim 9 wherein coupling the semiconductor device that is one of the diode includes coupling one of a P-N diode, a diode coupled bipolar transistor, or an LED as the semiconductor device.

11. The method of claim 10 wherein coupling the semiconductor device includes coupling the semiconductor device to allow the current to flow in one direction through the first FET but block the current from flowing in an opposite direction through the first FET.

12. The method of claim 9 wherein coupling the semiconductor device includes coupling the semiconductor device to a gate and a source of the first FET wherein the semiconductor device increases a gate-to-source voltage of the first FET as temperature increases and decreases the gate-to-source voltage as temperature decreases.

13. The method of claim 9 wherein coupling the semiconductor device includes coupling the semiconductor device to a gate and a source of the first FET wherein the semiconductor device and the first FET decrease the current as temperature increases and increases the current as temperature decreases.

14. The method of claim 9 wherein coupling the semiconductor device includes coupling the semiconductor device so that, at a given temperature, a gate-to-source voltage of the first FET varies which maintains variations of the current to no greater than about five percent.

15. The method of claim 9 further including a second FET in parallel with the combination of the first FET and the active semiconductor device including connecting a first current carrying electrode of the second FET to the first current carrying electrode of the first FET, connecting a gate of the second FET to the gate of the first FET, and coupling a second current carrying electrode of the second FET to the common node.

16. A method of forming a current source comprising:
coupling a first current carrying electrode of a first FET to receive a current to conduct through the first FET;
coupling an active semiconductor device that is one of a diode or a depletion mode MOSFET between a second current carrying electrode of the first FET and a common node of the current source wherein a voltage across the active semiconductor device varies from changes in temperature; and
configuring the current source to use changes in a voltage across the active semiconductor device to adjust a gate-to-source voltage of the first FET.

17. The method of claim 16 wherein configuring the current source to use changes in the voltage includes configuring the current source to monitor the voltage across the active semiconductor device and responsively adjust a gate-to-source voltage of the first FET.

18. The method of claim 17 wherein configuring the current source to monitor the voltage across the active semiconductor device includes coupling an amplifier to monitor a voltage from a gate of the first FET to the common node and control the gate-to-source voltage responsively to changes in the voltage across the active semiconductor device.

19. The method of claim 16 further including coupling a second FET in parallel with the combination of the first FET and the active semiconductor device wherein the second FET has a first current carrying electrode coupled to the first current carrying electrode of the first FET and a gate coupled to the gate of the first FET.

20. The method of claim 16 wherein coupling the active semiconductor device includes coupling one of a P-N diode, a diode coupled bipolar transistor, or an LED, as the active semiconductor device.

21. A method of forming a current source comprising:
providing a substrate of a first conductivity type and having first and second surfaces;
forming a first doped region having a second conductivity type on the first surface of the substrate;
forming a second doped region having the second conductivity type on the first surface of the substrate and spaced apart from the first doped region;
forming a region of the first conductivity type between the first and second doped regions;
forming third and fourth doped regions of the second conductivity type on the first surface and within the first doped region as respective source and drain regions of a depletion mode transistor;
forming a fifth doped region having the first conductivity type on the first surface and within the first doped region wherein the fifth doped region is spaced apart from and between the third and fourth doped regions;
forming a sixth doped region having the first conductivity type on the first surface and within the second doped region;
forming a seventh doped region having the second conductivity type on the first surface and within the sixth doped region; and
forming a first conductor to electrically couple the third doped region to the sixth doped region.

22. The method of claim 21 wherein forming the first doped region and forming the second doped region includes forming the first and second doped regions simultaneously with simultaneous process operations, wherein forming the fifth doped region and forming the sixth doped region includes forming the fifth and sixth doped regions simultaneously with simultaneous process operations, and wherein forming the fourth doped region and forming the seventh doped region includes forming the fourth and seventh doped regions simultaneously with simultaneous process operations.

23. The method of claim 21 wherein forming the first conductor to electrically connect the third doped region to the sixth doped region includes forming the first conductor to electrically connect the third doped region to the second doped region.
